(19) United States
(12) Patent Application Publication
(10) Pub. No.: US 2018/0102330 A1
(43) Pub. Date: Apr. 12, 2018

(54) SENSING CHIP PACKAGE HAVING ESD PROTECTION AND METHOD MAKING THE SAME

(71) Applicant: SunASIC Technologies, Inc., New Taipei City (TW)

(72) Inventors: Chung-Hao HSIEH, New Taipei City (TW); Chi-Chou LIN, Taipei (TW); Zheng-Ping HE, Taipei (TW)

(73) Assignee: SunASIC Technologies, Inc., New Taipei City (TW)

(21) Appl. No.: 15/291,111

(22) Filed: Oct. 12, 2016

(51) Int. Cl. H01L 23/60; H01L 23/00; H01L 23/31; H01L 21/56; H01L 21/48

(52) U.S. Cl. CPC H01L 23/60; H01L 24/49; H01L 23/3121; H01L 24/09; H01L 2224/4903; H01L 21/56; H01L 21/4853; H01L 2224/48091; H01L 24/85

(57) ABSTRACT

A chip package having ESD protection and a method for making the chip are disclosed. The chip package includes a chip and a substrate. The chip includes a number of I/O pads each connected to a corresponding I/O contact via a first bonding wire. It also includes a number of ESD protective pads each connected to a corresponding ESD contact via a second bonding wire. Bonding wires connecting the ESD protective pads and the ESD contacts have vertexes closer to the top surface of the chip than the vertexes of the bonding wires connecting the I/O pads and the I/O contacts. Hence, a perfect ESD protection effect is achieved by leading the ESD through the bonding wires to the ESD contacts rather than via the I/O contacts.

### FIELD OF THE INVENTION

The present invention relates to a chip package and a method for making the chip package. More particularly, the present invention relates to a sensing chip package which has enhanced ESD (Electro-Static Discharge) immunity and a method for making the sensing chip package.

### BACKGROUND OF THE INVENTION

Integrated Circuits (ICs) are susceptible to Electrostatic Discharge (ESD) damage. This damage may occur during manufacturing, shipping, or under an uncontrollable use condition or use environment. Many ESD standards, such as Human Body Model (HBM), Machine Model (MM), and Charged Device Model (CDM), have been developed to ensure the performance and robustness of electronic devices during manufacturing processes. Processes, such as packaging, shipping, placing and soldering, following the standards above are all performed in an environment that the ESD condition to which the device is exposed is limited. These standards ensure the IC survives under the manufacturing processes and then the IC is assembled into a system. However, some important changes in today's systems increase ESD vulnerability thereof. The decrease in manufacturing geometries makes it is very difficult to provide adequate on-chip protection. The changing application environment makes a higher demand of ESD protection. For instance, laptops, smartphones, USB flash drives, and other handheld devices are used in uncontrollable environments where people touch I/O pins and/or sensing components (some are sensing ICs). These makes additional systematic level ESD protective design for exposed items more important.

A commonly applied technique for an exposed sensing IC, such as a fingerprint sensing chip, is illustrated in FIG. 1. A fingerprint sensing chip 10 is designed with an ESD protective structure close to the top surface (such as an ESD grid). At least one ESD protective pad 11 which is connected to the ESD protective structure and is used to conduct ESD current induced by an ESD source, i.e. a finger. The ESD protective pad will not be used to transfer signal for operating the fingerprint sensing chip 10. When the fingerprint sensing chip 10 is mounted on a PCB 12, there must be a corresponding ESD releasing contact 13 on the PCB 12. The ESD protective pad 11 is connected to the ESD releasing contact 13 by a bonding wire 14. After all pads are linked to the corresponding contacts, the all pads, contacts and bonding wires connecting therebetween are sealed by a molding compound 15 (packaged into a system). This technique is simple to implement. If an ESD source (such as a human finger) is on the surface of the fingerprint sensing chip 10, accumulated electric charges will be released to the PCB 12 through the ESD protective structure, further to the external environment, the ESD protective pad 11, the bonding wire 14 and the ESD releasing contact 13. If the ESD source touches the most portion of sealed region, since the non-conductive material is thick enough to resist electrical stress that causes dielectric breakdown, the packaged fingerprint sensing chip is safe from the damage of ESD. If the ESD source is close to the highest point of the arc of the I/O bonding wire 16 where the molding compound is thin, ESD stress is so high that electrical breakdown in the molding compound may occur (a situation similar to a lightning rod), further giving the ESD current an opportunity to attack the fingerprint sensing chip via the I/O pad 17. Thus, area around the highest point of the arc of the I/O bonding wire 16 prone to impair ESD immunity of the packaged fingerprint sensing chip.

In order to settle the problem mentioned above, there are many ways provided in the prior arts. Please refer to FIG. 2. A packaging of a fingerprint sensor and a method thereof disclosed by U.S. Pat. No. 8,736,001 is shown. A fingerprint sensor 30 includes a substrate 35, a fingerprint sensing chip 34 mounted on the substrate 35, and bonding wires 32 coupling the substrate 35 and the fingerprint sensing chip 34. The fingerprint sensing chip 34 includes a finger sensing area on an upper surface. The fingerprint sensor 30 includes an encapsulating layer 33 encapsulating the fingerprint sensing chip 34 and covering the fingerprint sensing area. The encapsulating layer 33 includes a recessed portion 37 for receiving the finger of the user. The encapsulating layer 33 also includes a peripheral flange portion 38 on the substrate 35 and surrounding the fingerprint sensing chip 34 and the bonding wires 32. The fingerprint sensor 30 includes a bezel 31 on the encapsulating layer. The bezel 31 may be coupled to circuitry to serve as a drive electrode for driving the finger of the user. The fingerprint sensor 30 includes conductive traces 36 on the substrate 35 for coupling the bezel 31 thereto. The bezel 31 may include a metal or another conductive material. In some examples, ESD protection circuitry may be coupled to the bezel 31. The bezel 31 is affixed on an uppermost surface of the encapsulating material (at the level higher than that of the highest point of the bonding wire) which means a step between the surface of the sensing area and top surface of the bezel is subject to the loop height of the bonding wires 32, which is around 100 μm in normal cases. Use of the bezel 31 may protect the fingerprint sensing chip 34 from mechanical and/or electrical damages. However, the bezel 31 causes an extra thickness for the whole fingerprint sensor 30 and thus is not suitable for the products that need to be flat and/or thin, such as a smart card or a smart phone. The fingerprint sensing chip 34 must include the bezel 31. This increases cost and limits the appearance of the fingerprint sensing chip 34.

Another prior art providing solution for ESD protection is shown in FIG. 3. It is disclosed by US patent application No. 2006/0071320. A semiconductor device 50 includes a number of package pins 51, a chip 52, a number of first bonding pads 53, a number of second bonding pads 54, a number of first bonding wires 55, and a number of second bonding wires 56. The package pins 51 are constructed from a conductive material and further connected to external circuits. A semiconductor integrated circuit (LSI) is included on the chip 52. The LSI preferably includes an ESD protection circuit 57 and an I/O circuit 58. The first and second bonding pads 53 and 54 are both electrically conductive thin films of the same shape/size, and further made of metal. The first and second bonding pads 53 and 54 are formed on the chip 52 with a fixed pitch along the perimeter of the chip 52. The first bonding pads 53 are formed at the peripheral parts of the chip 52, while the second bonding pads 54 are formed inside the peripheral parts. Each of the first bonding pads 53 is paired with one of the second bonding pads 54 that is located at a predetermined distance.

The first bonding wire 55 connects the first bonding pad 53 directly to the package pin 51, and is used as a signal line between them. The second bonding wire 56 connects the second bonding pad 54 directly to the package pin 51, and is used as a signal line between them. The second bonding wire 56 is provided with a sufficiently longer length than the first bonding wire 55. A longer bonding wire has, in general, a higher parasitic inductance it is. Accordingly, the second bonding wire 56 can be provided with a sufficiently higher parasitic inductance than the first bonding wire 55. Accordingly, when an ESD causes an excessive surge voltage at the package pin 51, for example, the entailed surge current flows mainly through the first bonding pad 53 to the ESD protection circuit 57. Thus, the I/O circuit 58 connected to the second bonding pad 54 is reliably protected from malfunctions and destruction caused by the ESD. Although 2006/0071320 provides a smart skill to bypass ESD with different parasitic inductances of bonding wires, however, the method is not suitable for the packaging of a sensor with an active area on the same (top) surface as where bonding pads locate. In respect of the top surface of the chip 52, the first bonding wire 55 is relatively lower than the second bonding wire 56. Therefore, the second bonding wire 56 acts resembling a lightning rod while an ESD source comes close to the top surface of the chip 52. ESD has great chance to hit the second bonding wire 56. The I/O circuit 58 may be damaged.

There is still no suitable solution to the above ESD protection problem. Therefore, an innovative design of a chip package having ESD protection is desired.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In order to settle the problem mentioned above, a chip package having ESD protection is provided. The chip package includes: a chip, including: a functional operating unit; a number of I/O pads, connected to the functional operating unit; and a number of ESD protective pads, connected to the functional operating unit, for leading electrostatic charges accumulated in the chip to external environment of the chip; and a substrate, for carrying the chip, a top side of the substrate including: a number of I/O contacts, each I/O contact connected to a corresponding I/O pad via a first bonding wire, wherein a loop height of one first bonding wire to the a top surface of the chip is less than a first height; and a number of ESD protective contacts, each ESD protective contact connected to a corresponding ESD protective pad via a second bonding wire, wherein a loop height of one second bonding wire to the top surface of the chip is less than a second height. The loop height of the first bonding wire is less than that of the second bonding wire.

The chip package preferably further includes: a packaging body, made of a packaging material, covering at least a portion of the chip, the pads, the bonding wires and a portion of the substrate. A sealing height from a top surface of the packaging body to the top surface of the chip is less than a third height.

According to the present invention, the ESD protective contacts are further connected to an ESD protective device. The ESD protective device may be an ESD proactive net or a TVS (Transient Voltage Suppressor). The packaging material may be a molding compound. All or portions of the I/O pads and ESD protective pads are substantially interleavedly arranged along a line on periphery of the chip. All or portions of the I/O pads may be substantially arranged along a line on periphery of the chip, and the ESD protective pads are arranged around the I/O pads. The chip may be a fingerprint sensing chip. The first height ranges from 30 μm to 60 μm. The second height is between the first height and the third height. The third height ranges from 70 μm to 100 μm.

Another aspect of the present is to provide a method for making the chip package mentioned above. The method includes the steps of: providing the substrate; placing the chip on the top side of the substrate with the I/O pads and ESD protective pads facing up; connecting each I/O pad to a corresponding I/O contact by wire bonding, wherein the loop height of the first bonding wire to the top surface of the chip is less than the first height; and connecting each ESD protective pad to a corresponding ESD protective contact by wire bonding, wherein the loop height of the second bonding wire to the top surface of the chip is less than the second height. The loop height of the first bonding wire is less than that of the second bonding wire.

The method preferably further includes the steps of: sealing a portion of the chip and the bonding wires with a molding compound on the substrate to form a packaging body and maintaining a sealing height from a top surface of the packaging body to the top surface of the chip less than a third height.

It is obvious from the above that the bonding wires connecting the ESD protective pads and the ESD contacts have vertexes closer to the top surface of the chip (operating area) than the vertexes of the bonding wires connecting the I/O pads and the I/O contacts. Hence, a perfect ESD protection effect is achieved by leading the ESD through the bonding wires to the ESD contacts rather than the I/O contacts.

### BRIEF DESCRIPTION OF THE DRAWINGS

FIG. 1 is a schematic diagram illustrating a conventional technique used for ESD protection for a fingerprint sensing chip.

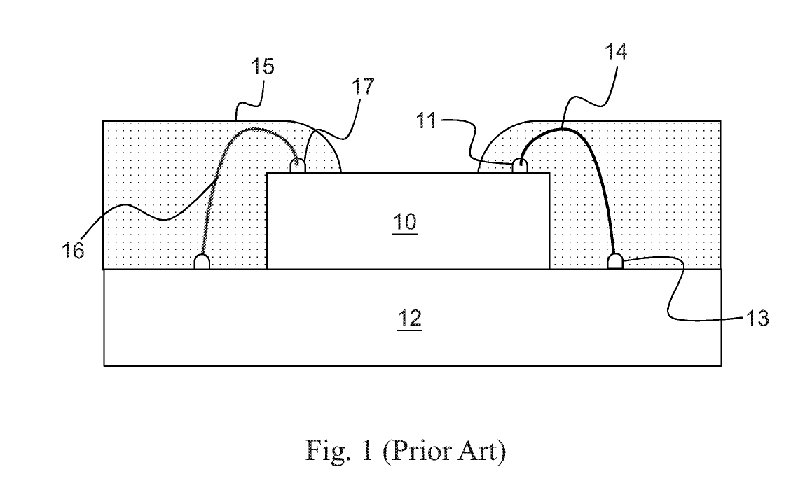

FIG. 2 show a conventional design used for ESD protection for a fingerprint sensing chip.

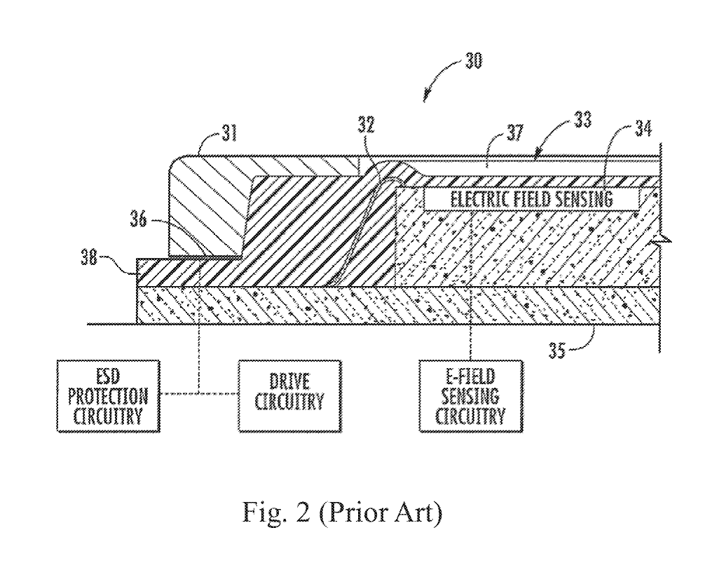

FIG. 3 shows another conventional design used for ESD protection for a fingerprint sensing chip.

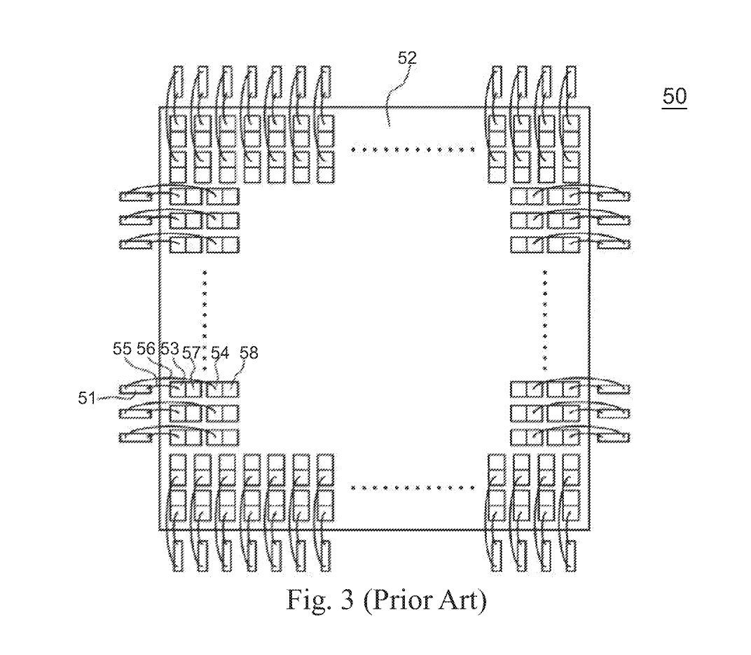

FIG. 4 is a schematic diagram of a chip package having ESD protection according to the present invention.

FIG. 5 is a top view of a fingerprint sensing chip with a functional operating unit, I/O pads and ESD protective pads.

FIG. 6 is a flow chart of a method for making the chip package.

FIG. 7 is another top view of a fingerprint sensing chip with a functional operating unit, I/O pads and ESD protective pads.

FIG. 8 is a schematic diagram of another chip package having ESD protection according to the present invention.

### DETAILED DESCRIPTION OF THE PREFERRED EMBODIMENTS

The present invention will now be described more specifically with reference to the following embodiments.

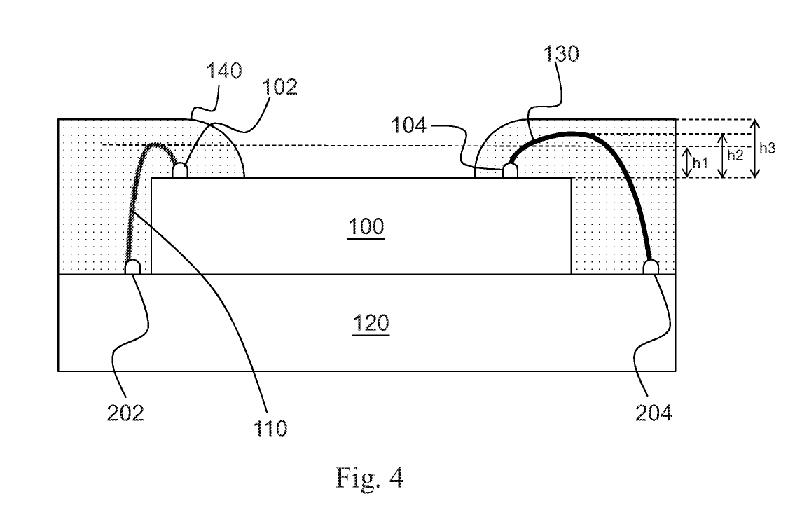

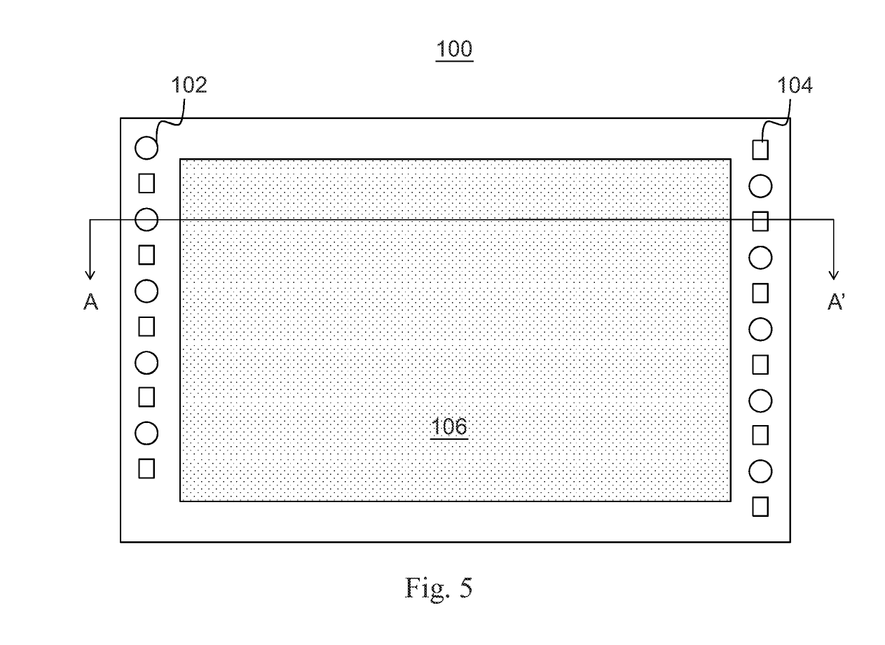

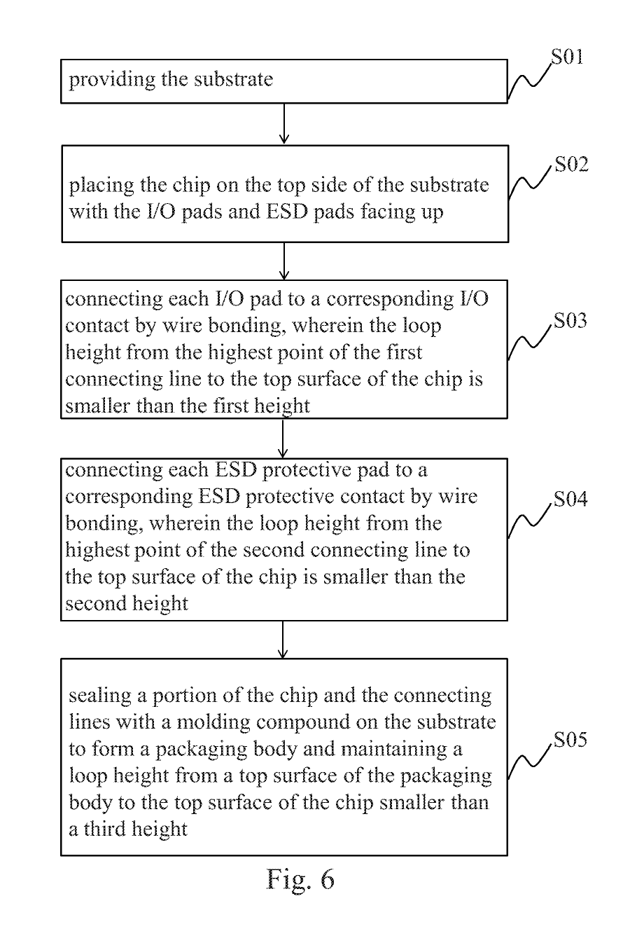

Please refer to FIGS. 4 to 6. An embodiment of a chip package having ESD protection according to the present invention is disclosed. FIG. 4 is a schematic diagram of the chip package. FIG. 5 is a top view of a chip 100 of the chip package with a functional operating unit 106, I/O pads 102 and ESD protective pads 104. FIG. 6 is a flow chart of a method for making the chip package. FIG. 4 and FIG. 5 are corresponding. For illustration purpose, proportion of each element in FIG. 4 and FIG. 5 may not be exactly the same as it is. The chip package mainly includes a chip 100, a substrate 120 and a packaging body 140. Each of the above elements has some specific design features that are different from what are applied nowadays. Functions and features of the elements are illustrated below.

The chip 100 used in the present invention better has a sensing function with a portion of the chip 100 exposed to the external environment or has a very thin protective film (with a thickness less than 20 um) above said exposed part. In this embodiment, the chip 100 is a fingerprint sensing chip. In other embodiments, it may be a CMOS image chip. The chip 100 has three main sub-elements: a functional operating unit 106, a number of I/O pads 102 and a number of ESD protective pads 104. Please see FIG. 4 and FIG. 5 at the same time. FIG. 4 is available by drawing a cross-sectional view along line AA′ in FIG. 5. For illustrative purpose, the I/O pads 102 are drawn in a shape of a circle and the ESD protective pads 104 are drawn in a shape of a rectangle to make a distinction, although their real external shape may be neither a circle nor a rectangle. The functional operating unit 106 is where the chip 100 provides its specific function. In this embodiment, it is a fingerprint sensing area, composed of an array of sensing elements. The I/O pads 102 are connected to the functional operating unit 106. They are used for sending out signals from the chip 100 to an external circuit, receiving signals from the external circuit linked to it, and providing power for the chip 100 from an external power source. The ESD protective pads 104 are connected to some ESD protective structures (not shown), such as a metal grid at top-most metal layer of the chip 100, in the functional operating unit 106. They are used for leading electrostatic charges accumulated in the chip 100 to external environment of the chip 10, e.g. leads on to a PCB that may further connect to an earth ground. In fact, general I/O pads of chips have been designed to have ESD protection ability against 2˜4 KV. It is often done by utilizing pMOS and nMOS inside the chip and/or connecting some diodes with the I/O pad. The ESD protective pad 104 mentioned here is another type that is not used for signal transmission. On the contrary, the ESD protective pad 104 is used only to protect the chip 100 against ESD damage. It can undertake ESD voltage at 15 KV or more. Especially, the ESD protective pads 104 work when the chip 100 is operating, rather than being under manufacturing, and protect the chip 100 from the ESD source coming closer to the I/O pads 102 from the top side of chip 100. ESD pulse will not damage the chip 100 through the I/O pads 102 but drain out of the chip 100 via bonding wires linked to the ESD protective pads 104.

The substrate 120 can carry the chip 100. In practice, it can be a PCB. A top side of the substrate 120 has a number of I/O contacts 202 and a number of ESD protective contacts 204. Each I/O contact 202 is connected to a corresponding I/O pad 102 via a first bonding wire 110, and each ESD protective contact 204 is connected to a corresponding ESD protective pad 104 via a second bonding wire 130. Both the first bonding wire 110 and the second bonding wire 130 are achieved using wire bonding method. A bounding wire basically forms a curve-like side view, and a height from the highest point of one bounding wire to a top surface of the chip is called “loop height”. The loop height of one first bonding wire 110 should be limited and be less than a first height. As shown in FIG. 4, for each first bonding wire 110, the loop height is shown by h1. From experiments, the first height is better ranges from 30 μm to 60 μm. Similarly, the loop height of one second bonding wire 130 should also be limited and lower than a second height but much higher than the first height. As shown in FIG. 4, for each second bonding wire 130, the height is shown by h2. The second height is better 65 μm. The ESD protective contacts 204 can be further connected to an ESD protective device mounted on the substrate 120 (not shown) to effectively bypass the ESD current to an ESD path (not shown) on the substrate 120. An ESD path is a circuit designed for draining out ESD current to avoid any damage of the components on a substrate caused by ESD current. In practice, the ESD protective device may be ESD proactive net or a TVS.

The packaging body 140 is made of a packaging material. It covers at least a portion of the chip 100 (exposing the functional operating unit 106), the pads (I/O pads 102 and ESD protective pads 104), the bonding wires (first bonding wires 110 and second bonding wires 130) and at least a portion of the substrate 120. The packaging body 140 is used to seal the chip 100 (except the functional operating unit 106 in this embodiment, but in some other embodiments, the functional operating unit 106 may be also sealed into the packaging body 140), the substrate 120 and all pads and bonding wires for preventing physical damage and corrosion. A sealing height, h3, from a top surface of the packaging body 140 to the top surface of the chip 100 should be lower than a third height but much higher than the second height for providing enough thickness to protect the bonding wires. The third height should range from 70 μm to 110 μm. It is clear that the second height is in a range between the first height and third height. In practice, the second height is better to be set as an average value of the first height and the third height. As to the material, the packaging material is better a molding compound.

Arrangement of the I/O pads 102 and ESD protective pads 104 is important according to the present invention. One I/O pad 102 should come along with at least one ESD protective pad 104 nearby. Therefore, any ESD encountered can be led away by the adjacent ESD protective pad(s) 104 via the second bonding wire(s) 130 which is higher in height. An example of the arrangement is shown in FIG. 5. On two sides of the chip 100 (periphery), all the I/O pads 102 and ESD protective pads 104 are substantially interleavedly arranged along a line. If pads of the chip 100 have to be located within a very crowd space, there may not be one-to-one relationship between the I/O pads 102 and ESD protective pads 104, portions of the I/O pads 102 and ESD protective pads 104 should be arranged as mentioned above, as many as possible.

Please refer to FIG. 6. FIG. 6 is a flow chart of a method for making the chip package. The method has below steps. First, provide the substrate 120 (S01). Then place the chip 100 on the top side of the substrate 120 with the I/O pads 102 and ESD protective pads 104 facing up (S02). Connect each I/O pad 102 to a corresponding I/O contact 202 by wire bonding. The loop height of the first bonding wire 110 to the top surface of the chip 100 is less than the first height (S03). Then, connect each ESD protective pad 104 to a corresponding ESD protective contact 204 by wire bonding. The loop height of the second bonding wire 130 to the top surface of the chip 100 is less than the second height (S04). However, in practice, the sequence of the step S03 and S04 may exchange, or probably, the step S03 and S04 take place at the same time. It is not limited by the present invention. Finally, seal a portion of the chip 100 and the bonding wires with a molding compound on the substrate 120 to form a packaging body 140 and maintain a sealing height from a top surface of the packaging body 140 to the top surface of the chip 100 less than a third height (505).

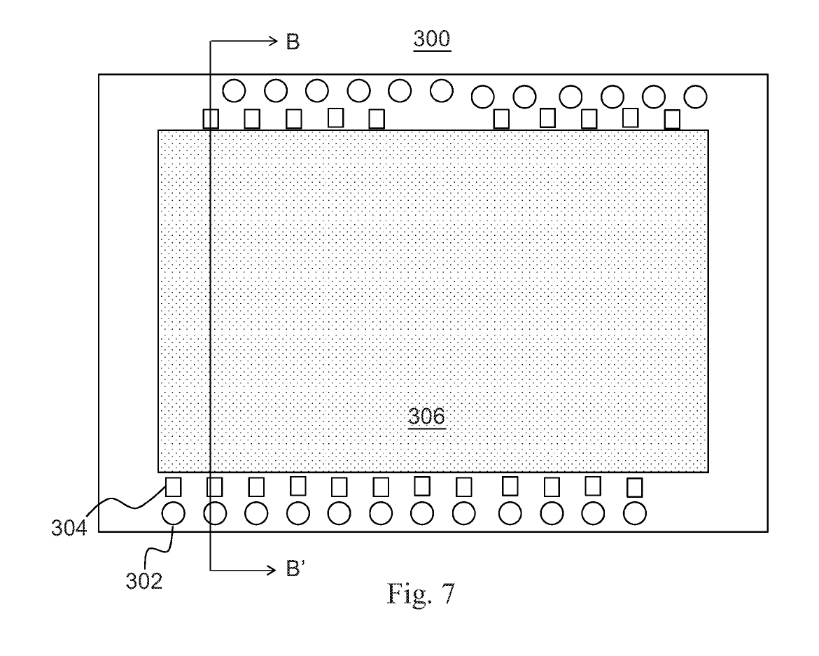

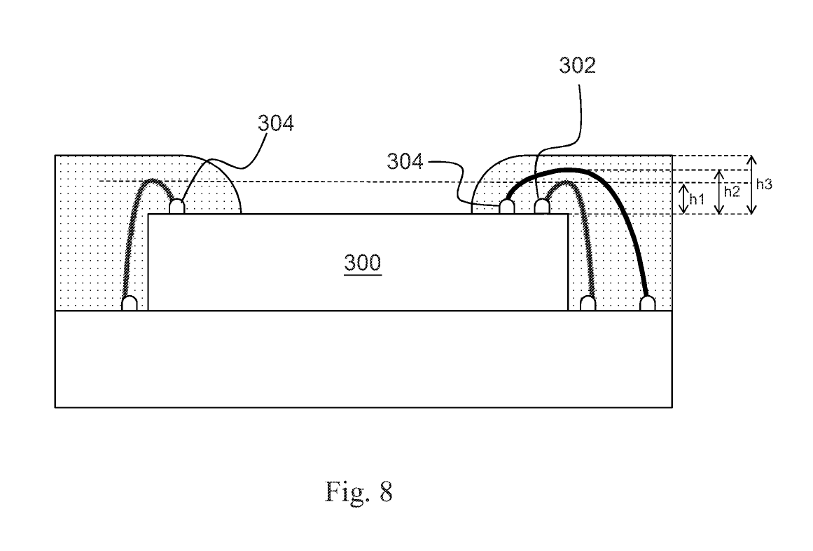

In another embodiment, arrangement of the I/O pads and ESD protective pads may be different from the previous embodiment. Please refer to FIG. 7 and FIG. 8. Another chip 300 has a functional operating unit 306, I/O pads 302 and ESD protective pads 304. It is obvious that all of the I/O pads 302 are substantially arranged along a line on the bottom side (periphery) of the chip 300. The ESD protective pads 304 on the same side are arranged around the I/O pads 302 (not all I/O pads 302 and ESD protective pads 304 are arranged along the same line). Portions of the I/O pads 302 on the top side are substantially arranged along a line but others are not. The ESD protective pads 304 are still designed to be arranged around the I/O pads 302. No matter which type of the arrangements on two side, they are applicable according to the present invention. It is also obvious from FIG. 8 that a loop height of the bonding wire of the ESD protective pads 304 is higher than that of the I/O pad 302. It means the bonding wire of the ESD protective pads 304 can protect the I/O pads 302 by draining away any ESD pulse since it gets closer to an ESD source near the surface of the chip 300.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. An chip package having ESD (Electro-Static Discharge) protection, comprising:
a chip, comprising:
a functional operating unit;
a plurality of I/O pads, connected to the functional operating unit; and
a plurality of ESD protective pads, connected to the functional operating unit, for leading electrostatic charges accumulated in the chip to external environment of the chip; and
a substrate, for carrying the chip, a top side of the substrate comprising:
a plurality of I/O contacts, each I/O contact connected to a corresponding I/O pad via a first bonding wire, wherein a loop height of one first bonding wire to the a top surface of the chip is less than a first height; and
a plurality of ESD protective contacts, each ESD protective contact connected to a corresponding ESD protective pad via a second bonding wire, wherein a loop height of one second bonding wire to the top surface of the chip is less than a second height,
wherein the loop height of the first bonding wire is less than that of the second bonding wire.

2. The chip package according to claim 1, further comprising:
a packaging body, made of a packaging material, covering at least a portion of the chip, the pads, the bonding wires and a portion of the substrate, wherein a sealing height from a top surface of the packaging body to the top surface of the chip is less than a third height.

3. The chip package according to claim 1, wherein the ESD protective contacts are further connected to an ESD protective device.

4. The chip package according to claim 3, wherein the ESD protective device is an ESD proactive net or a TVS (Transient Voltage Suppressor).

5. The chip package according to claim 2, wherein the packaging material is a molding compound.

6. The chip package according to claim 1, wherein all or portions of the I/O pads and ESD protective pads are substantially interleavedly arranged along a line on periphery of the chip.

7. The chip package according to claim 1, wherein all or portions of the I/O pads substantially are arranged along a line on periphery of the chip, and the ESD protective pads are arranged around the I/O pads.

8. The chip package according to claim 1, wherein the chip is a fingerprint sensing chip.

9. The chip package according to claim 1, wherein the first height ranges from 30 μm to 60 μm.

10. The chip package according to claim 2, wherein the second height is between the first height and the third height.

11. The chip package according to claim 2, wherein the third height ranges from 70 μm to 110 μm.

12. A method for making the chip package in claim 1, comprising the steps of:
providing the substrate;
placing the chip on the top side of the substrate with the I/O pads and ESD protective pads facing up;
connecting each I/O pad to a corresponding I/O contact by wire bonding, wherein the loop height of the first bonding wire to the top surface of the chip is less than the first height; and
connecting each ESD protective pad to a corresponding ESD protective contact by wire bonding, wherein the loop height of the second bonding wire to the top surface of the chip is less than the second height,
wherein the loop height of the first bonding wire is less than that of the second bonding wire.

13. The method according to claim 12, further comprising the steps of: sealing a portion of the chip and the bonding wires with a molding compound on the substrate to form a packaging body and maintaining a sealing height from a top surface of the packaging body to the top surface of the chip less than a third height.

14. The method according to claim 12, wherein the first height ranges from 30 μm to 60 μm.

15. The method according to claim 13, wherein the second height is between the first height and the third height.

16. The method according to claim 13, wherein the third height ranges from 70 μm to 110 μm.
